(19) United States
(12) Patent Application Publication
(10) Pub. No.: US 2026/0100293 A1
(43) Pub. Date: Apr. 9, 2026

(54) MECHANICALLY ROBUST COMPOSITE STRUCTURES WITH FORMED ELECTRICAL PATHS

(71) Applicant: Applied Materials, Inc., Santa Clara, CA (US)

(72) Inventors: Robert MAY, Santa Clara, CA (US); Sarah WOZNY, Santa Clara, CA (US); Gopalakrishna B. PRABHU, San Jose, CA (US); Marvin Louis BERNT, Kalispell, MT (US)

(21) Appl. No.: 18/905,932

(22) Filed: Oct. 3, 2024

(51) Int. Cl. H01B 5/16; H01B 1/02; H01B 3/02; H01B 3/08; H01B 19/04; H01L 21/48; H01L 23/498

(52) U.S. Cl. CPC H01B 5/16; H01B 1/026; H01B 19/04; H10W 70/05; H10W 70/095; H10W 70/65; H10W 70/685; H10W 70/69; H01B 3/025; H01B 3/084

(57) ABSTRACT

Embodiments of the disclosure describe a method that includes disposing an electrical insulator material over a layer of a ceramic-based material having vias and solid portions between the vias. The vias are filled with an electrically conductive metal that forms electrical paths through the layer of the ceramic-based material. A composite structure is formed that includes portions of the electrical insulator material that are fixed to the solid portions of the layer of the ceramic-based material. The composite structure further includes regions positioned between the portions of the electrical insulator material. The electrical insulator material has a first coefficient of thermal expansion (CTE), the electrically conductive metal has a second CTE, and the ceramic-based material has a third CTE that is greater than the first CTE and less than the second CTE.

### BACKGROUND

### Field

Embodiments described herein generally relate to systems and methods for manufacturing components used in semiconductor devices. More specifically, embodiments of the present disclosure relate to systems and methods for manufacturing structures for use in semiconductor devices.

### Description of the Related Art

Substrates having electrical connections that extend through the substrates are commonly used components in semiconductor devices. Typically, these components include a dielectric material such as glass or semiconducting materials such as silicon having through vias filled with an electrically conductive material to form the electrical connections. However, the dielectric material is often susceptible to cracking (and crack propagation), especially if there is a significant difference between the coefficients of thermal expansion (CTE) of the electrically conductive material and the dielectric material. Additionally, for high aspect ratio features, like the through vias, to extend through the dielectric material, a thickness of the dielectric material is typically limited to a few hundred micrometers, which is generally not thick enough for controlling package warpage.

Accordingly, there is a need in the art for a method and apparatus that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the disclosure describe a method that includes disposingan electrical insulator material over a layer of a ceramic-based material having vias and solid portions between the vias. The vias are filled with an electrically conductive metal that forms electrical paths through the layer of the ceramic-based material. A composite structure is formed that includes portions of the electrical insulator material that are fixed to the solid portions of the layer of the ceramic-based material. The composite structure further includes regions positioned between the portions of the electrical insulator material. The electrical insulator material has a first coefficient of thermal expansion (CTE), the electrically conductive metal has a second CTE, and the ceramic-based material has a third CTE that is greater than the first CTE and less than the second CTE.

Embodiments of the present disclosure describe a composite structure having a layer of a ceramic-based material that includes electrically conductive paths extending through the ceramic-based material and solid portions positioned between the electrically conductive paths. A first layer of an electrical insulator material is positioned over the layer of the ceramic-based material and bonded to first ends of the solid portions. A second layer of the electrical insulator material is positioned under the layer of the ceramic-based material and bonded to second ends of the solid portions. The electrical insulator material has a first coefficient of thermal expansion (CTE), an electrically conductive metal forming the electrically conductive paths has a second CTE, and the ceramic-based material has a third CTE that is greater than the first CTE and less than the second CTE.

Embodiments of the present disclosure describe a method that includes disposing an electrical insulator material over a layer of a ceramic-based material having vias and solid portions between the vias. The vias are filled with an electrically conductive metal that forms electrical paths through the layer of the ceramic-based material. The method further includes bonding portions of the electrical insulator material to the solid portions of the layer of the ceramic-based material. The electrical insulator material includes apertures positioned over the vias. The method further includes filling the apertures positioned over the vias with the electrically conductive metal and extending the electrical paths through the electrical insulator material.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a bonding system, in accordance with certain embodiments of the present disclosure.

FIG. 2 illustrates a process flow diagram of a method for bonding portions of layers of an electrical insulator material to solid portions of a layer of a ceramic-based material, in accordance with certain embodiments of the present disclosure.

FIG. 3 is a schematic representation of forming vias through a layer of a ceramic-based material, in accordance with certain embodiments of the present disclosure.

FIG. 4 is a schematic representation of filling vias with an electrically conductive metal, in accordance with certain embodiments of the present disclosure.

FIG. 5 illustrates examples of disposing an electrical insulator material over a layer of a ceramic-based material, in accordance with certain embodiments of the present disclosure.

FIG. 6A is a schematic representation of bonding portions of a first layer of an electrical insulator material to first ends of solid portions of a layer of a ceramic-based material, in accordance with certain embodiments of the present disclosure.

FIG. 6B is a schematic representation of bonding portions of a second layer of an electrical insulator material to second ends of solid portions of a layer of a ceramic-based material, in accordance with certain embodiments of the present disclosure.

FIG. 6C is a schematic representation of filling apertures with an electrically conductive metal, in accordance with certain embodiments of the present disclosure.

FIG. 7 is a schematic representation of stacked composite structures, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to systems and methods for manufacturing components used in semiconductor devices. More specifically, embodiments of the present disclosure relate to systems and methods for manufacturing composite structures with formed electrical paths for use in semiconductor devices. In some embodiments, a layer of an electrical insulator or semiconducting material (e.g., silicon, glass, other materials, etc.) is positioned over a layer of a ceramic-based material (e.g., a low temperature co-fired ceramic (LTCC) material).

In various embodiments, one or more first portions of the layer of the electrical insulator material are bonded to one or more second portions of the layer of the ceramic-based material. The one or more first portions and the one or more second portions can be bonded using a thermal bond. In some examples, anodic bonding is utilized to bond the one or more first portions and the one or more second portions at a relatively low temperature. Bonding the one or more first portions to the one or more second portions reduces a likelihood that the layer of the electrical insulator material will become cracked. Bonding the one or more first portions to the one or more second portions may also prevent or mitigate propagation of cracks within the layer of the electrical insulator material.

### Bonding System Examples

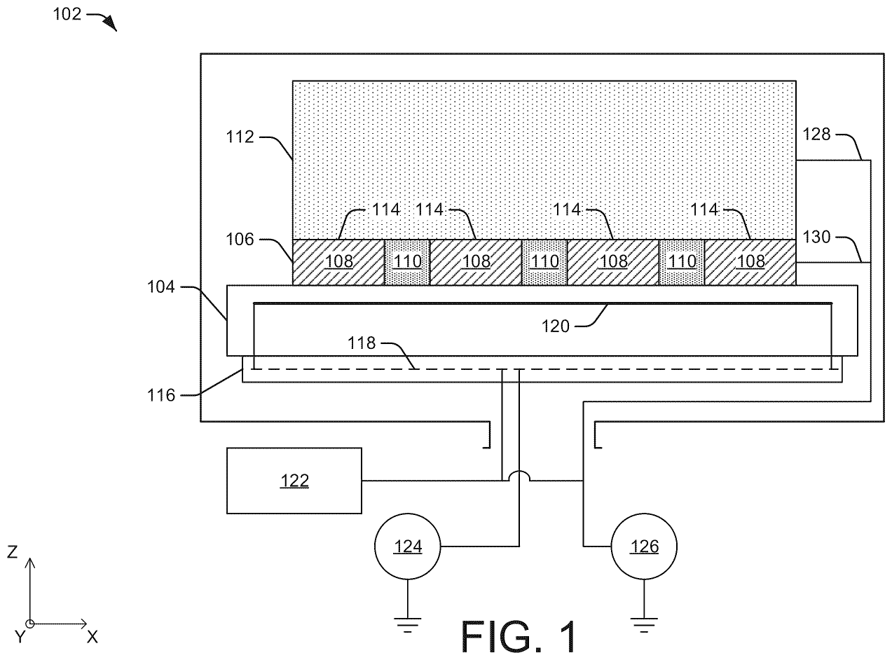

FIG. 1 is a schematic cross-sectional view of a bonding system 102. The bonding system 102 includes a support structure 104 which is illustrated to be positioned within, or disposed within, an optional processing chamber. In some embodiments, instead of being positioned within the optional processing chamber, the support structure 104 is positioned within an autoclave. In other embodiments, the support structure 104 is included in an environment in which processing can be performed at relatively high temperatures (e.g., greater than ambient temperatures).

A layer 106 of a ceramic-based material is positioned on the support structure 104 in FIG. 1. The layer 106 of the ceramic-based material includes solid portions 108 and electrical paths 110 which extend through the layer 106 between the solid portions 108. In one or more embodiments, the ceramic-based material is a non-homogeneous material of varying composition. In some embodiments, the ceramic-based material includes a low temperature co-fired ceramic (LTCC) material. For example, the ceramic-based material can include aluminum oxide and/or glass.

Electrical insulator material 112 is positioned over the layer 106 of the ceramic-based material. The electrical insulator material 112 is to be bonded to the layer 106 of the ceramic-based material to form a composite structure with the electrical paths 110. In some embodiments, the electrical insulator material 112 includes silicon or a silicon-based material. In other embodiments, the electrical insulator material 112 includes glass or a glass-based material. In various embodiments, the electrical insulator material 112 may include another type of material. In the example shown in FIG. 1, the electrical insulator material 112 is non-patterned. However, as described below, the electrical insulator material 112 may be patterned (e.g., include pre-formed apertures) in various embodiments.

In one or more embodiments, the bonding system 102 is configured to form the composite structure with the electrical paths 110 by bonding portions 114 of the electrical insulator material 112 to the solid portions 108 of the layer 106 of the ceramic-based material. In order to form the composite structure, a printed circuit board (PCB) 116 is positioned below the support structure 104. A heater 120 is positioned within the support structure 104 and the heater 120 is electrically coupled to a circuit layer 118 of the PCB 116. A controller 122 is communicatively coupled (e.g., electrically coupled) to the circuit layer 118 of the PCB 116. In some embodiments, the controller 122 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 122 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

The PCB 116 (e.g., the circuit layer 118) includes multiple transistors (e.g., MOSFETs) configured as switches. In various examples, the controller 122 is capable of controlling the transistors of the circuit layer 118 to selectively deliver power from a power source 124 to the heater 120 and/or to cause a voltage source 126 to apply a DC bias to electrodes 128, 130. In some embodiments, delivering power to the heater 120 by the power source 124 transfers heat to the support structure 104 which delivers heat to the layer 106 of the ceramic-based material and the electrical insulator material 112. In various embodiments, heating the layer 106 of the ceramic-based material and the electrical insulator material 112 is configured to thermally bond the portions 114 to the solid portions 108.

In some embodiments, the electrical insulator material 112 has a first coefficient of thermal expansion (CTE), an electrically conductive material forming the electrical paths 110 has a second CTE, and the ceramic-based material has a third CTE that is greater than the first CTE and less than the second CTE. Accordingly, heating the layer 106 of the ceramic-based material and the electrical insulator material 112 at a particular temperature causes the electrically conductive material forming the electrical paths 110, the electrical insulator material 112, and the ceramic-based material to expand by different amounts. As described below, in one or more embodiments, the third CTE of the ceramic-material may be selected based on a difference between the first CTE of the electrical insulator material 112 and the second CTE of the electrically conductive material forming the electrical paths 110. For example, the first CTE may be about 2 to 6 parts per million per degree Celsius (ppm/° C.) and the second CTE may be about 17 ppm/° C. In this example, the third CTE can be selected to minimize stresses caused by the difference between the first CTE and the second CTE. In various embodiments, one or more other properties of the ceramic-based material can be selected to minimize the stresses caused by differences between the first and second CTEs such as firing shrinkage percentages of the ceramic-based material.

In one or more embodiments, the heater 120 is capable of heating the layer 106 of the ceramic-based material and the electrical insulator material 112 at temperatures greater than or equal to about 750 degrees Celsius (° C.) such as temperatures in a range of about 800 to 900° C. In certain embodiments, the heater 120 is capable of heating the layer 106 of the ceramic-based material and the electrical insulator material 112 at temperatures of about 1100° C. or greater. In some embodiments, heating the layer 106 of the ceramic-based material and the electrical insulator material 112 thermally bonds the portions 114 of the electrical insulator material 112 to the solid portions 108 of the layer 106 of the ceramic-based material by forming interfacial bonds between the portions 114 and the solid portions 108, by forming diffusion bonds between the portions 114 and the solid portions 108, and/or by forming other types of bonds between the portions 114 and the solid portions 108. In certain embodiments, one or more forces (e.g., due to a pressure maintained within the optional processing chamber of the bonding system 102) may be applied to the electrical insulator material 112 and/or the layer 106 of the ceramic-based material during a thermal bonding process. In various examples, the one or more forces applied to the electrical insulator material 112 and/or the layer 106 of the ceramic-based material urge surfaces of the portions 114 and surfaces of the solid portions 108 closer together, for example, to increase bond strength of the thermal bond.

In some embodiments, it may be undesirable to heat the electrical insulator material 112 and/or the layer 106 of the ceramic-based material at temperatures greater than a threshold temperature. For example, at temperatures greater than the threshold temperature, one or more materials included in the electrical insulator material 112 and/or the layer 106 of the ceramic-based material are above corresponding melting points of the one or more materials. In order to bond the portions 114 of the electrical insulator material 112 to the solid portions 108 of the layer 106 of the ceramic-based material at temperatures less than or equal to, for example, about 400° C., the one or more processors of the controller 122 execute instructions that cause the one or more processors to control the transistors of the circuit layer 118 and cause the voltage source 126 to apply the DC bias to electrodes 128, 130 for anodic bonding of the portions 114 and the solid portions 108. The DC bias induces ion migration and causes an electrostatic force between materials which facilitates bonding of the materials at lower temperatures than needed to thermally bond the materials.

In one or more embodiments, the voltage source 126 applies a DC bias in a range of about 300 to 900 V such as about 500 V to the electrodes 128, 130 as part of the anodic bonding process. As shown in FIG. 1, the electrode 128 is coupled to the electrical insulator material 112 and the electrode 130 is coupled to the layer 106 of the ceramic-based material. If the electrical insulator material 112 includes silicon, then the controller 122 causes the voltage source 126 to apply the DC bias to the electrodes 128, 130 such that the electrode 128 is configured as a cathode (a negative electrode) and the electrode 130 is configured as an anode (a positive electrode) because silicon does not include mobile cations. If the electrical insulator material 112 includes glass, then the controller 122 causes the voltage source 126 to apply the DC bias to the electrodes 128, 130 such that the electrode 128 is configured as the anode (the positive electrode) and the electrode 130 is configured as the cathode (the negative electrode) because glass includes mobile cations such as mobile alkali ions. In various embodiments, by utilizing the voltage source 126 to apply the DC bias to the electrodes 128, 130, the portions 114 of the electrical insulator material 112 can be bonded to the solid portions 108 of the layer 106 of the ceramic-based material at temperatures in a range of about 200 to 400° C. Notably, the heater 120 may be utilized in the anodic bonding process to heat the layer 106 of the ceramic-based material and the electrical insulator material 112 at temperatures in the range of about 200 to 400° C.

Bonding (with or without anodic bonding) the portions 114 of the electrical insulator material 112 to the solid portions 108 of the layer 106 of the ceramic-based material forms the composite structure with the electrical paths 110. Once formed, the composite structure with the electrical paths 110 is mechanically robust. For example, the layer 106 of the ceramic-based material reduces a likelihood of cracks forming in the electrical insulator material 112. The layer 106 of the ceramic-based material may also reduce a risk that cracks formed in the electrical insulator material 112 will propagate. As described further below, the composite structure with the electrical paths 110 has additional benefits relative to conventional non-composite structures. In some examples, the composite structure with the electrical paths 110 can be stacked on top of other composite structures to extend the electrical paths 110 and also to control package warpage based on a thickness of the stacked composite structures.

### Composite Structure Examples

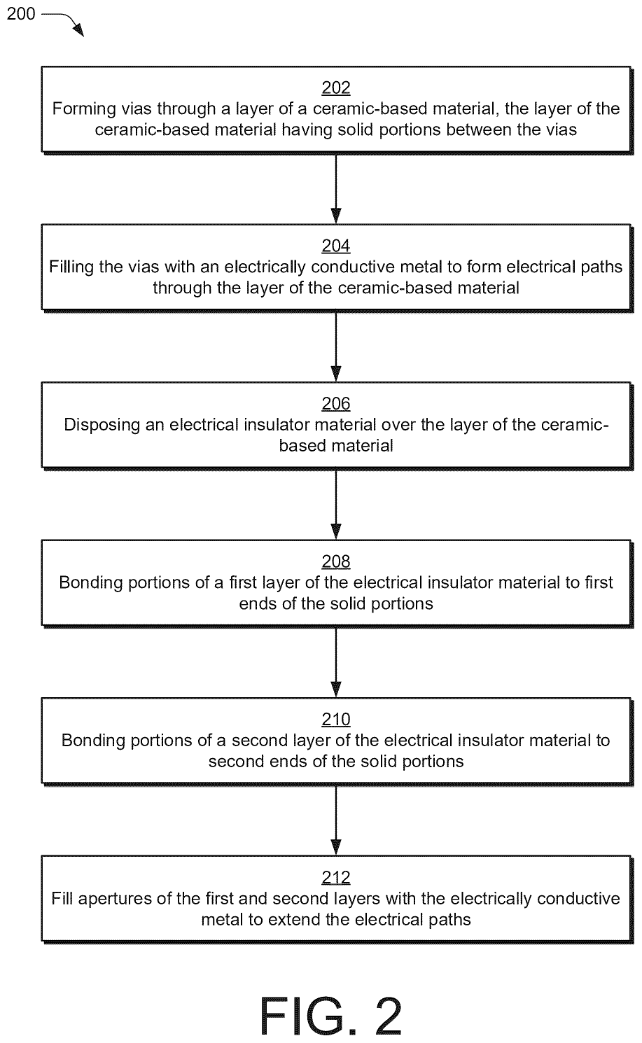

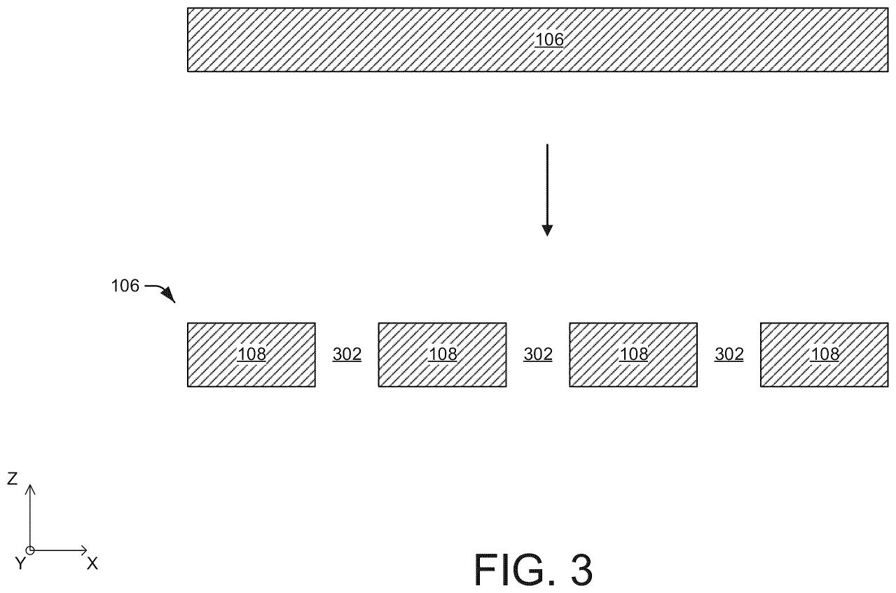

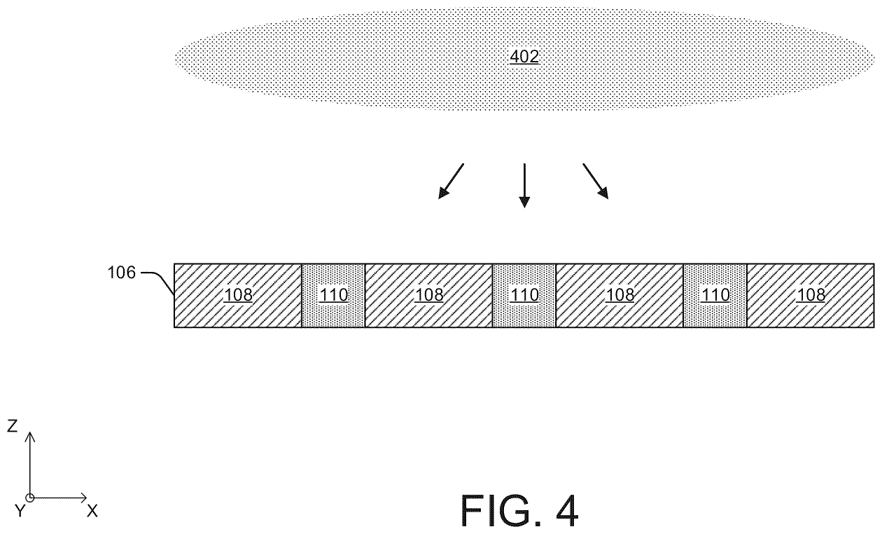

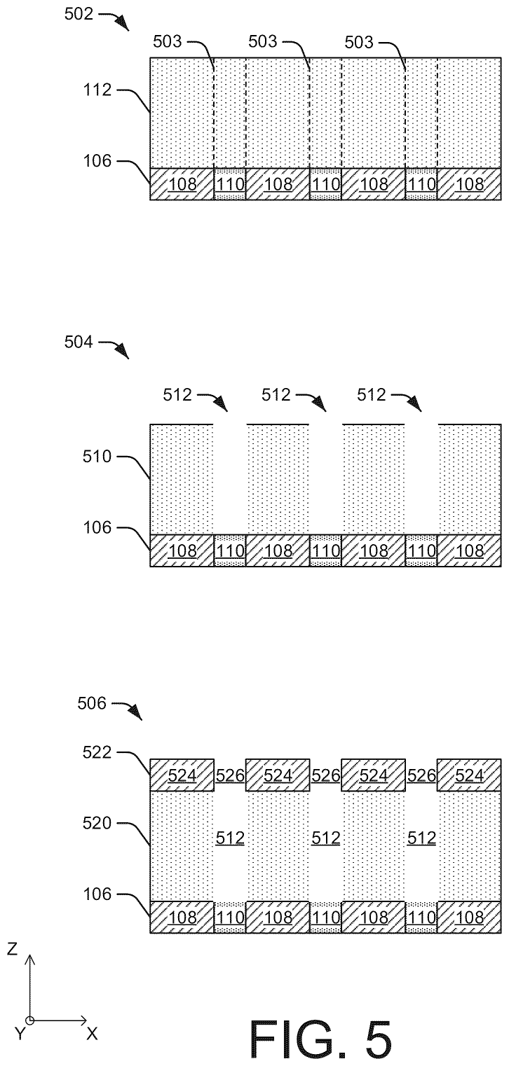

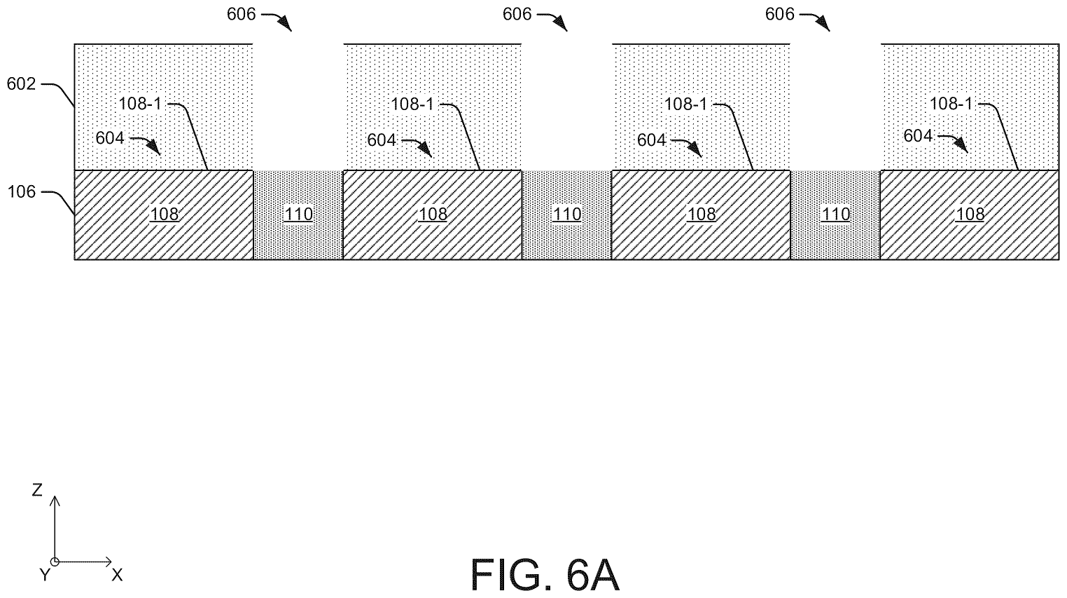

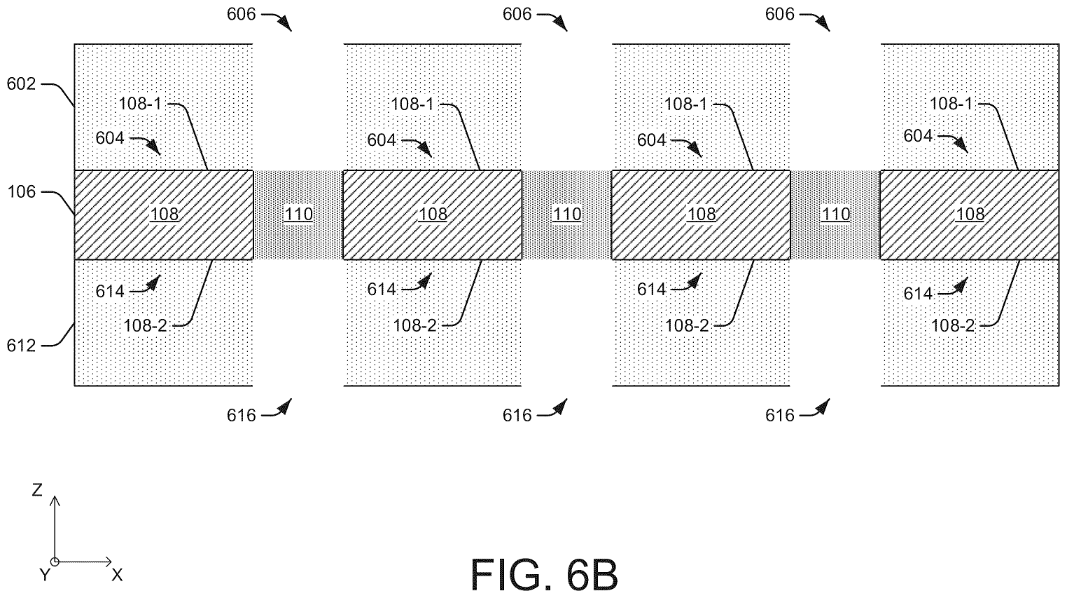

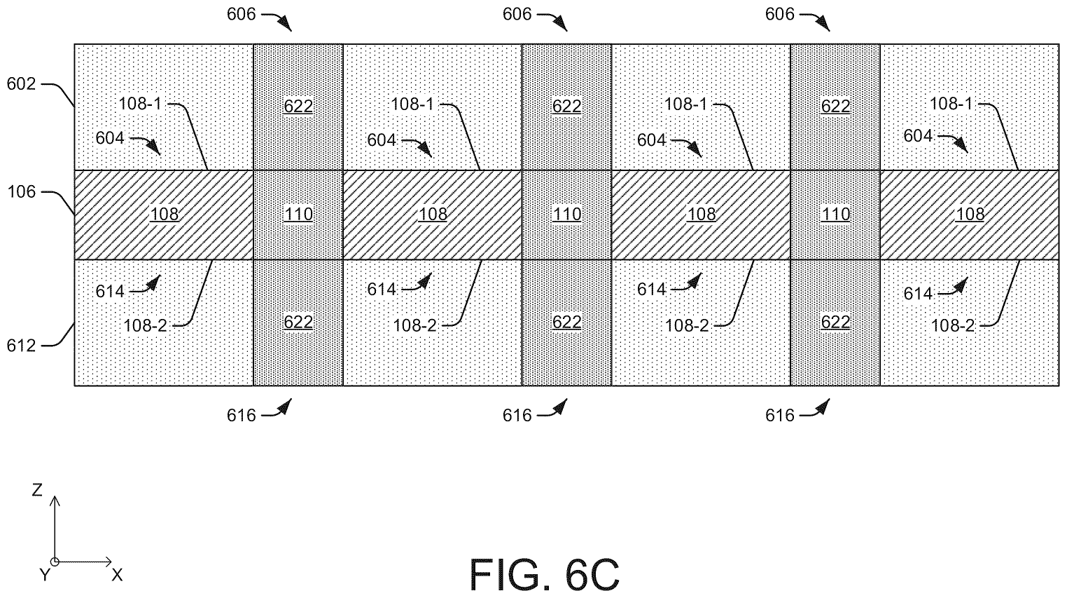

FIG. 2 illustrates a process flow diagram of a method 200 for bonding portions of layers of an electrical insulator material to solid portions of a layer of a ceramic-based material. FIG. 3 is a schematic representation of forming vias 302 through a layer 106 of a ceramic-based material. FIG. 4 is a schematic representation of filling vias 302 with an electrically conductive metal 402. FIG. 5 illustrates examples of disposing an electrical insulator material over a layer 106 of a ceramic-based material FIG. 6A is a schematic representation of bonding portions 604 of a first layer of an electrical insulator material 602 to first ends 108-1 of solid portions 108 of a layer 106 of a ceramic-based material. FIG. 6B is a schematic representation of bonding portions 614 of a second layer of an electrical insulator material 612 to second ends 108-2 of solid portions 108 of a layer 106 of a ceramic-based material. FIG. 6C is a schematic representation of filling apertures 606, 616 with an electrically conductive metal 622.

At operation 202, vias are formed through a layer of a ceramic-based material, the layer of the ceramic-based material having solid portions between the vias. With reference to FIG. 3, the layer 106 of the ceramic-based material is modified to include vias 302 between the solid portions 108 of the layer 106. In certain embodiments, the ceramic-based material may include an alumina powder and a glass powder mixed together to form the layer 106. In various embodiments, the ceramic-based material can include a low temperature co-fired ceramic (LTCC). In one or more examples, the layer 106 of the ceramic-based material may have a thickness in a range of about 30 to 200 micrometers (μm). The ceramic-based material may have an associated firing shrinkage in a range of about 10 to 15 percent such as about 12.8 percent in the X-direction and the Y-direction. The ceramic-based material can have an associated firing shrinkage in a range of about 25 to 35 percent such as about 32 percent in the Z-direction. In some embodiments, the layer 106 of the ceramic-based material is stamped to form the vias 302 between the solid portions 108. In other embodiments, the vias 302 can be formed using one or more other processes such as cutting, drilling, punching, or another process.

At operation 204, the vias are filled with an electrically conductive metal to form electrical paths through the layer of the ceramic-based material. With respect to FIG. 4, an electrically conductive metal 402 is formed within the vias 302 to form electrical paths 110 through the layer 106 of the ceramic-based material. The electrically conductive metal 402 can include copper, tungsten, molybdenum, a metal alloy, and/or other electrically conductive materials (and combinations of materials). In some embodiments, the electrically conductive metal 402 is deposited in the vias 302 using a deposition process such as a physical vapor deposition (PVD) process, a chemical vapor deposition (CVD) process, a plasma-based deposition process, or another type of deposition process. Notably, it is to be appreciated that, in various embodiments, the electrically conductive metal 402 may be deposited in the vias 302 using a variety different processes and techniques.

At operation 206, an electrical insulator material is positioned over the layer of the ceramic-based material. With reference to FIG. 5, in example 502, the electrical insulator material 112 that is non-patterned is positioned over the layer 106 of the ceramic-based material. In some embodiments, portions of the electrical insulator material 112 above the solid portions 108 are bonded to the solid portions 108 using the heater 120 (with or without anodic bonding) as described above. As shown, regions 503 are positioned between the portions of the electrical insulator material 112 above the solid portions 108. In example 502, the regions 503 include additional portions of the electrical insulator material 112 positioned over the electrical paths 110.

In example 504, an electrical insulator material 510 is positioned over the layer 106 of the ceramic-based material. A shown, the electrical insulator material 510 is patterned and includes apertures 512 that are positioned over the electrical paths 110. Unlike example 502 in which the regions 503 include the additional portions of the electrical insulator material 112 positioned over the electrical paths 110, in example 504, the regions 503 include the apertures 512 that expose the electrical paths 110. Portions of the electrical insulator material 510 above the solid portions 108 are bonded to the solid portions 108 using the heater 120 (with or without anodic bonding) as described above. In some embodiments, an electrically conductive material such as the electrically conductive metal 402 can be positioned in the apertures 512 in order to fill the apertures 512 with the electrically conductive material and extend the electrical paths 110.

In example 506, an electrical insulator material 520 is positioned over the layer 106 of the ceramic-based material and the electrical insulator material 520 is patterned to include the apertures 512. In various embodiments, the electrical insulator material 520 also includes an additional layer 522 of material such as the ceramic-based material or another material. The additional layer 522 of material includes solid portions 524 and vias 526 positioned between the solid portions 524. As shown in FIG. 5, the vias 526 are positioned over the apertures 512 in some embodiments. In various embodiments, the apertures 512 can be filled with the electrically conductive material (e.g., the electrically conductive metal 402) to extend the electrical paths 110. In these embodiments, the electrically conductive material may also be positioned in the vias 526 to further extend the electrical paths 110.

At operation 208, portions of a first layer of the electrical insulator material are bonded to first ends of the solid portions. With respect to FIG. 6A, portions 604 of a first layer of the electrical insulator material 602 are bonded to first ends 108-1 of the solid portions 108 of the layer 106 of the ceramic-based material. As shown, the first layer of the electrical insulator material 602 is positioned over the layer 106 of the ceramic-based material. In various embodiments, the portions 604 are bonded to the first ends 108-1 of the solid portions 108 using the heater 120 (with or without anodic bonding) as described above. In some embodiments, the first layer of the electrical insulator material 602 includes apertures 606, for example, the first layer of the electrical insulator material 602 is patterned to include the apertures 606. In one or more embodiments, the apertures 606 are positioned over the electrical paths 110 such that the electrical paths 110 are exposed.

In some embodiments, the first layer of the electrical insulator material 602 and the layer 106 of the ceramic-based material form a portion of a composite structure that exhibits benefits relative to conventional components utilized in semiconductor devices. For example, a coefficient of thermal expansion (CTE) and/or firing shrinkage percentages can be selected for the ceramic-based material in order to compensate for the CTE mismatch between the electrically conductive metal 402 that forms the electrical paths 110 and the first layer of the electrical insulator material 602. In certain embodiments, the first layer of the electrical insulator material 602 has a first CTE, the electrically conductive metal 402 that forms the electrical paths 110 has a second CTE, and the layer 106 of the ceramic-material has a third CTE that is greater than the first CTE and less than the second CTE. For example the first CTE of the electrically conductive metal 402 and the second CTE of the first layer of the electrical insulator material 602 may differ by as much as 10 ppm/° C. or more. In some embodiments, the difference between the first CTE and the second CTE can be mitigated by selecting the third CTE for the ceramic-based material to be between the first CTE and the second CTE. In one or more examples, the layer 106 of the ceramic-based material can be used to minimize an impact of adding routing layers to the composite structure by disposing the layer 106 of the ceramic-based material between the routing layers and the first layer of the electrical insulator material 602.

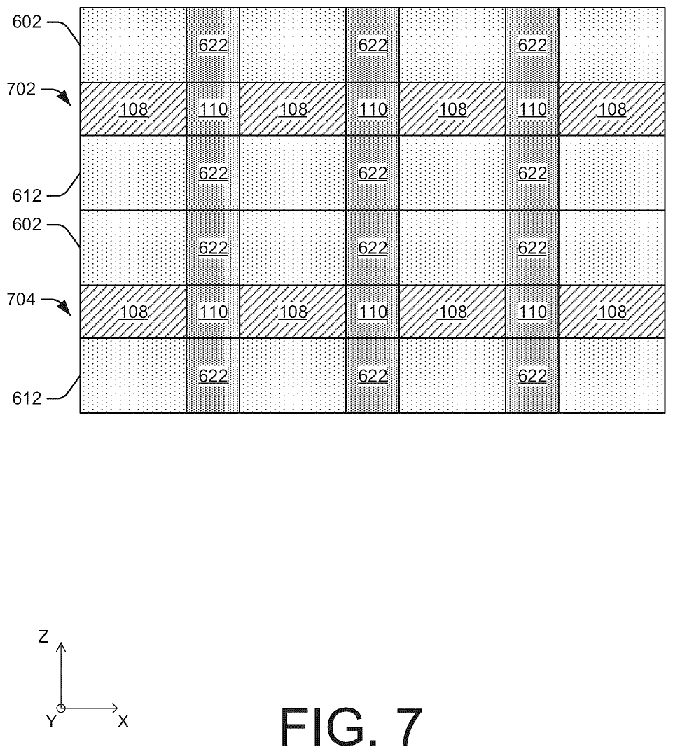

In various embodiments, the ceramic-based material and/or one or more properties of the layer 106 of the ceramic-based material may be selected to reduce a likelihood that the first layer of the electrical insulator material 602 becomes cracked. In addition to reducing the likelihood of crack formation in the first layer of the electrical insulator material 602, the layer 106 of the ceramic-based material can prevent or mitigate propagation of existing cracks in the first layer of the electrical insulator material 602. In one or more embodiments, the composite structure can also be stacked with other composite structures as described further relative to FIG. 7.

At operation 210, portions of a second layer of the electrical insulator material are bonded to second ends of the solid portions. With reference to FIG. 6B, portions 614 of a second layer of the electrical insulator material 612 are bonded to second ends 108-2 of the solid portions 108 of the layer 106 of the ceramic-based material. As shown, the second layer of the electrical insulator material 612 is positioned under the layer 106 of the ceramic-based material. In some embodiments, the portions 614 are bonded to the second ends 108-2 of the solid portions 108 using the heater 120 (with or without anodic bonding) as described above. In one or more embodiments, the second layer of the electrical insulator material 612 is patterned and includes apertures 616. Similar to the apertures 606, the apertures 616 are positioned over the electrical paths 110.

At operation 212, apertures of the first and second layers are filled with the electrically conductive metal to extend the electrical paths. With respect to FIG. 6C, the apertures 606, 616 are filled with an electrically conductive metal 622 (or another electrically conductive material) to extend the electrical paths 110. In some embodiments, the electrically conductive metal 622 is the same as the electrically conductive metal 402. In other embodiments, the electrically conductive metal 622 may be different from the electrically conductive metal 402. As shown in FIG. 6C, a composite structure includes the electrical paths 110 extended through the composite structure by filling the apertures 606, 616 with the electrically conductive metal 622.

FIG. 7 is a schematic representation of stacked composite structures 702, 704. As shown, the composite structure 702 is similar or the same as the composite structure included in FIG. 6C and the composite structure 704 is also similar or the same as the composite structure included in FIG. 6C. In some embodiments, the composite structures 702, 704 have form factors and geometries configured for stacking the composite structures 702, 704. In one or more embodiments, the composite structure 702 can be stacked on the composite structure 704 or the composite structure 704 may be stacked on the composite structure 702. Extended electrical paths 110 of the composite structure 702 are aligned with extended electrical paths 110 of the composite structure 704. For example, the extended electrical paths 110 of the composite structure 702 may be connected to the extended electrical paths 110 of the composite structure 704. In some embodiments, the extended electrical paths 110 of the composite structures 702, 704 may have a relatively high density (e.g., the extended electrical paths 110 may have relatively large cross-sectional areas). In one or more embodiments, by stacking the composite structures 702, 704 such that the extended electrical paths 110 are aligned, a thickness of the composite structures 702, 704 in the Z-direction is independent from the size of a diameter (e.g., a cross-sectional area) of the extended electrical paths 110 in the X-direction and the Y-direction. In these embodiments, the thickness of the composite structures 702, 704 is increasable to control (e.g., prevent) package warpage. This is an improvement relative to conventional interposers/substrates utilized in semiconductor devices which are limited to dependencies between core thickness (in the Z-direction) and through electrical conductor diameter sizes (in the X-direction and the Y-direction).

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or processes described with respect to one implementation may be combined with the features, components, and/or processes described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more operations or actions for achieving the described method. The method operations and/or actions may be interchanged with one another without departing from the scope of the claims. In other words, unless a specific order of operations or actions is specified, the order and/or use of specific operations and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A method comprising:
disposing an electrical insulator material over a layer of a ceramic-based material having vias and solid portions between the vias, wherein the vias are filled with an electrically conductive metal that forms electrical paths through the layer of the ceramic-based material; and
forming a composite structure that includes:
portions of the electrical insulator material that are fixed to the solid portions of the layer of the ceramic-based material; and
regions positioned between the portions of the electrical insulator material, wherein the electrical insulator material has a first coefficient of thermal expansion (CTE), the electrically conductive metal has a second CTE, and the ceramic-based material has a third CTE that is greater than the first CTE and less than the second CTE.

2. The method of claim 1, further comprising:
bonding first portions of the portions of the electrical insulator material to first ends of the solid portions; and
bonding second portions of the portions of the electrical insulator material to second ends of the solid portions.

3. The method of claim 2, further comprising:
filling apertures of the regions with the electrically conductive metal to extend the electrical paths through the electrical insulator material.

4. The method of claim 1, wherein the regions include additional portions of the electrical insulator material positioned over the electrical paths.

5. The method of claim 1, wherein the electrical insulator material includes at least one of glass or silicon and the ceramic-based material includes aluminum oxide.

6. The method of claim 1, wherein the electrically conductive metal includes at least one of copper, tungsten, or molybdenum.

7. The method of claim 1, wherein the electrically conductive metal includes a metal alloy.

8. The method of claim 1, further comprising bonding the portions of the electrical insulator material to the solid portions of the layer of the ceramic-based material.

9. The method of claim 8, wherein the bonding includes thermal bonding at a temperature greater than or equal to 750 degrees Celsius.

10. The method of claim 8, wherein the bonding includes thermal bonding at a temperature less than or equal to 400 degrees Celsius.

11. The method of claim 10, wherein the bonding includes anodic bonding.

12. A composite structure comprising:
a layer of a ceramic-based material that includes electrically conductive paths extending through the ceramic-based material and solid portions positioned between the electrically conductive paths;
a first layer of an electrical insulator material positioned over the layer of the ceramic-based material and bonded to first ends of the solid portions; and
a second layer of the electrical insulator material positioned under the layer of the ceramic-based material and bonded to second ends of the solid portions, wherein the electrical insulator material has a first coefficient of thermal expansion (CTE), an electrically conductive metal forming the electrically conductive paths has a second CTE, and the ceramic-based material has a third CTE that is greater than the first CTE and less than the second CTE.

13. The composite structure of claim 12, wherein the electrically conductive metal includes at least one of copper, tungsten, or molybdenum.

14. The composite structure of claim 12, wherein the electrical insulator material includes at least one of glass or silicon.

15. The composite structure of claim 12, further comprising:
first apertures of the first layer of the electrical insulator material, the first apertures positioned over the electrical paths; and
second apertures of the second layer of the electrical insulator material, the second apertures positioned under the electrical paths.

16. The composite structure of claim 15, wherein the first apertures and the second apertures are filled with the electrically conductive metal to extend the electrically conductive paths.

17. The composite structure of claim 12, wherein the ceramic-based material includes a low temperature co-fired ceramic (LTCC) material.

18. A method comprising:
disposing an electrical insulator material over a layer of a ceramic-based material having vias and solid portions between the vias, wherein the vias are filled with an electrically conductive metal that forms electrical paths through the layer of the ceramic-based material;
bonding portions of the electrical insulator material to the solid portions of the layer of the ceramic-based material, wherein the electrical insulator material includes apertures positioned over the vias;
filling the apertures positioned over the vias with the electrically conductive metal to extend the electrical paths through the electrical insulator material.

19. The method of claim 18, further comprising:
aligning the electrical paths with additional electrical paths of an additional layer of the ceramic-based material; and
connecting the electrical paths and the additional electrical paths.

20. The method of claim 18, wherein the portions of the electrical insulator material are bonded to the solid portions of the layer of the ceramic-based material at a temperature less than or equal to 400 degrees Celsius.
